(19) United States
(12) Patent Application Publication
(10) Pub. No.: US 2023/0342541 A1
(43) Pub. Date: Oct. 26, 2023

(54) METER DISPLAY IDENTIFICATION SYSTEM AND IDENTIFICATION METHOD

(71) Applicant: SHIMADZU CORPORATION, Kyoto (JP)

(72) Inventors: Haodong QIU, Shanghai (CN); Okiyuki KUNIHIRO, Shanghai (CN); Qi MAO, Shanghai (CN)

(73) Assignee: SHIMADZU CORPORATION, Kyoto (JP)

(21) Appl. No.: 18/134,409

(22) Filed: Apr. 13, 2023

(30) Foreign Application Priority Data
Apr. 24, 2022 (CN) 202210453279.3

(51) Int. Cl. G06F 40/20; G06Q 50/06; G02B 27/01

(52) U.S. Cl. CPC G06F 40/20; G06Q 50/06; G02B 27/017; G01R 11/04

(57) ABSTRACT

A meter display identification system and a meter display identification method for identifying type information of a meter included in a figure identification code displayed on the meter panel side of the meter, including an image acquisition module configured to collect image information, whose an imaging area includes a display area of the figure identification code and a display area of target data on the meter panel, of the meter panel, a meter type identification module configured to identify type information of the meter by identifying the figure identification code from image information collected by the image acquisition module, a text detection module configured to identify a display area of the target data based on the type information and a display area of the figure identification code, and a text identification module configured to perform text identification on image information in a display area of the target data are provided. According to the present invention, complexity of identification of a display area of target data is simplified, and efficiency of identification of the target data and accuracy of identification of the target data are improved.

### BACKGROUND OF THE INVENTION

### 1. Field of the Invention

The present invention relates to a technical field of reading of a meter panel, and specifically to a meter display identification system and an identification method.

### 2. Description of the Related Art

Currently, a measurement result of some preprocessing apparatuses (for example, an electronic balance) in a laboratory is usually artificially read and recorded. In this process, there are problems such as recording errors and leakage, and more time may be required. In some image identification systems, meter display of a preprocessing apparatus can be read by an optical character recognition (OCR) technique, but there is a case where, due to differences in configuration, data display position, and display mode between different apparatuses, read data cannot be quickly or directly introduced into a laboratory related information system such as a laboratory information management system (LIMS) or an electronic lab notebook (ELN). There is also a risk of data loss or falsification during transfer.

### SUMMARY OF THE INVENTION

An object of the present invention is to provide a meter display identification system and an identification method capable of overcoming a defect of the prior art and improving meter display identification accuracy and efficiency.

In order to achieve the above object, the present invention employs a technical idea below.

A meter display identification system for identifying type information of a meter included in a figure identification code displayed on the meter panel side of the meter is provided. The meter display identification system includes an image acquisition module configured to collect image information, whose an imaging area includes a display area of a figure identification code and a display area of target data on the meter panel, of the meter panel, a meter type identification module configured to identify the figure identification code from image information collected by the image acquisition module and identifies type information of a meter, a text detection module configured to identify the display area of target data based on type information and the display area of a figure identification code, and a text identification module configured to perform text identification on image information in the display area of target data.

When a pasting position or a display position of a figure identification code is fixed at the time of shipment, and a relative positional relationship between the figure identification code and a display area of both pieces of target data is also fixed, the present invention employs a means for individually identifying the figure identification code and the display area of target data, and identifies the display area of target data based on type information of a meter and a display area of the figure identification code, so that identification of a position of target data and a display area of target data is assisted based on a position of a figure identification code, a display area of target data can be quickly identified, complexity of identification of a display area of target data is simplified, a required calculation amount is reduced, and efficiency of identification of target data and accuracy of identification of target data are improved.

In a selectable technical idea of the present invention, the meter type identification module identifies type information of the meter, and the text detection module identifies a display area of the target data based on the type information. By identifying type information of a meter by the meter type identification module, calculation can be effectively simplified, and calculation efficiency in identification of a display area is improved.

In a selectable technical idea of the present invention, the image acquisition module is installed in a smart wearable device or a smart mobile device, and the text identification module sends a text identification result to the smart wearable device or the smart mobile device. According to this technical idea, image information can be conveniently and quickly collected by a smart wearable device or a smart mobile device, a text identification result can be received, meter display identification efficiency and a level of smartness in a meter reading number are increased, degree of human involvement is reduced, and an error rate, data loss, or a risk of falsification is reduced.

A selectable technical idea of the present invention further includes a database. The database stores type information of the meter, a display area of the figure identification code, and a display area of the target data in association with each other, and the database is obtained by learning of image information of meters of a plurality of specific types as a reference data set. According to this technical idea, meter type information in the database is compared with meter type information of the figure identification code, so that type information of a meter can be acquired, and the display area of a figure identification code in the database is compared with image information acquired by the image acquisition module, so that the display area of the figure identification code can be acquired, and the display area of target data is identified based on the display area of a figure identification code and the type information, or the display area of target data in the database is collated with the image information acquired by the image acquisition module, so that the display area of target data can be acquired, and accuracy of identification of the display area of target data can be improved. Further, since expanding information such as type information of a meter, the display area of a figure identification code, and the display area of target data in the database is advantageous to increase a sample amount in the database and improve collation efficiency, the display area of target data is acquired more quickly and identification efficiency of the identification system is improved.

A selectable technical idea of the present invention further includes a direction adjustment module for adjusting an angle of inclination or rotation of image information in a display area of the target data. According to this technical idea, an angle of inclination or rotation of image information is adjusted by the direction adjustment module, which is advantageous for obtaining a more accurate display area of target data, and improves accuracy of text identification.

In a selectable technical idea of the present invention, the direction adjustment module adjusts an angle of inclination or rotation of image information in a display area of the target data based on an angle of inclination or rotation of the figure identification code. According to this technical idea, accuracy of an angle of inclination or rotation identified by the direction adjustment module can be further improved, which in turn improves text identification efficiency.

A selectable technical idea of the present invention further includes a data output module that outputs identified text. According to this technical idea, by directly outputting data as compared with artificial recording and data transfer, for example, by outputting the data to a laboratory information management system, an electronic laboratory notebook, or the like, convenience and efficiency of data use are enhanced, and a risk of data loss and falsification is reduced.

In a selectable technical idea of the present invention, an identification result of the text identification module includes a text identification result and reliability corresponding to the text identification result. According to this technical idea, accuracy of a text identification result can be determined on the basis of a numerical value of reliability that is an evaluation numerical value by identification state determination of each part in an identification process.

In a selectable technical idea of the present invention, the figure identification code is a QR code provided in a display area of target data adjacent to a meter panel. According to this technical idea, since a QR code has advantages of low cost, easy production, excellent durability, and convenient identification, a configuration of the meter display identification system is simplified, cost of the meter display identification system is reduced, and identification efficiency of the meter display identification system is improved.

In a selectable technical idea of the present invention, the text detection module identifies size data of a display area of target data based on size data of a QR code in image information. According to this technical idea, by identifying size data of a display area of target data based on size data of a QR code, not only a position of the display area can be quickly identified, but also size and/or a shape of the display area can be quickly identified, which is advantageous for improving accuracy of identification of a target data display area, and improves accuracy of text identification.

Further, the present invention also provides a meter display identification method for identifying type information of a meter included in a figure identification code displayed on a meter panel side of the meter, the meter display identification method including the steps of:
collecting image information, whose an imaging area includes a display area of the figure identification code and a display area of target data on the meter panel, of the meter panel;
identifying the figure identification code from the image information and identifying type information of the meter;
identifying a display area of the target data based on the type information and a display area of the figure identification code; and
performing text identification on image information in a display area of the target data.

According to the present invention, complexity of identification of a display area of target data is simplified, and efficiency of identification of the target data and accuracy of identification of the target data are improved.

### BRIEF DESCRIPTION OF THE DRAWINGS

FIG. 1 is a schematic structural diagram of a meter display identification system according to a first embodiment of the present invention;

FIG. 2 is a schematic structural view of a meter panel according to the embodiment of the present invention;

FIG. 3 is a schematic flowchart of a meter display identification method according to the first embodiment of the present invention;

FIG. 4 is a schematic structural diagram of the meter display identification system according to a second embodiment of the present invention;

FIG. 5 is a schematic diagram of a database according to the second embodiment of the present invention;

FIG. 6 is a schematic structural diagram of the meter display identification system according to a third embodiment of the present invention;

FIG. 7 is a schematic flowchart of the meter display identification method according to the third embodiment of the present invention;

FIG. 8 is a schematic structural diagram of the meter display identification system according to a fourth embodiment of the present invention; and

FIG. 9 is a schematic flowchart of the meter display identification method according to the fourth embodiment of the present invention.

### DETAILED DESCRIPTION OF THE INVENTION

Hereinafter, a technical idea in an example of the present application will be described clearly and completely together with the drawings in the example of the present application. As a matter of course, described examples are not all the examples, but only some examples of the present application. All other examples obtained by a person of ordinary skill in the art based on an example of the present invention without work of an inventive step should belong to a protection scope of the present invention.

### First Embodiment

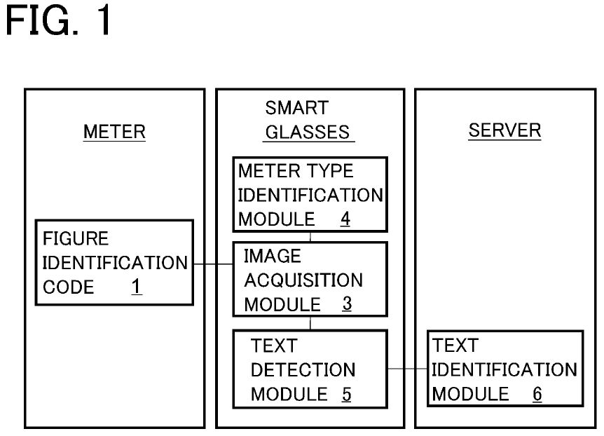

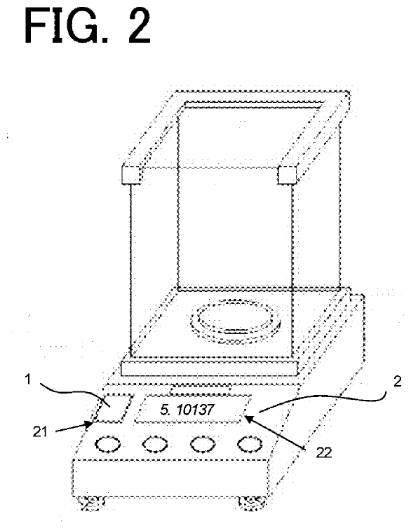

As illustrated in FIGS. 1 and 2, a first embodiment of the present invention provides a meter display identification system meter for identifying type information of a meter included in a figure identification code 1 displayed on the side of a meter panel of the meter. The figure identification code 1 is displayed on the side of a meter panel 2 of a meter (not illustrated). The figure identification code 1 has the type information of the meter. The meter display identification system includes an image acquisition module 3 that collects image information of the meter panel 2 whose imaging area includes a display area 21 of a figure identification code and a display area 22 of target data on the meter panel 2, a meter type identification module 4 that identifies the figure identification code 1 from image information collected by the image acquisition module 3 and identifies type information of a meter, a text detection module 5 that identifies the display area 22 of target data based on type information and the display area 21 of the figure identification code, and a text identification module 6 that performs text identification on image information in the display area 22 of target data.

When a pasting position or a display position of the figure identification code 1 is fixed at the time of shipment, and a relative positional relationship between the figure identification code 1 and the display area 22 of both pieces of target data is also fixed, the present invention acquires type information of a meter using the figure identification code 1 and identifies a display area of the target data based on the type information of the meter and the display area of the figure identification code, so that identification of a position and a display area of the target data is assisted based on the position of the figure identification code 1, the display area 22 of the target data can be quickly identified, and efficiency of identification of the target data and accuracy of identification of the target data are improved.

Specifically, the target data display area 21 and the display area 22 of a figure identification code are individually identified, which is advantageous to reduce complexity of image information identification and increase identification efficiency. Assisting identification of the display area 22 of target data using meter type information loaded with the figure identification code 1 after identification of the figure identification code 1 is performed is advantageous to reduce complexity of identification of the display area 22 of the target data, and also to contribute to improvement in identification efficiency. Performing text identification after the display area 22 of target data is locked on is advantageous to improve accuracy of text identification since interference of other pieces of irrelevant data on a meter panel is avoided.

In a preferred embodiment of the present invention, the figure identification code 1 is a QR code provided in the display area 22 of target data adjacent to the meter panel 2. Since a QR code has advantages of low cost, easy production, excellent durability, and convenient identification, a configuration of the meter display identification system is simplified, cost of the meter display identification system is reduced, and identification efficiency of the meter display identification system is improved.

In a specific example of the present invention, the figure identification code 1 is displayed on the meter panel side, which means that the figure identification code 1 and the meter panel are on the same surface of a meter, that is, both are on a front surface of the meter or on a side surface of the meter. Type information of a meter includes a device number, a device name, a device model, a device application, and the like. By detailed classification of type information of a meter, it is possible to avoid a situation in which efficiency of identifying a display area of target data is low or identification cannot be performed due to confusion between meters having similar functions and names, and accuracy and efficiency of a text recognition result are improved.

In a preferred embodiment of the present invention, the image acquisition module 3 is installed in a smart wearable device (not illustrated, for example, a head-mounted display such as smart glasses) or a smart mobile device (not illustrated), and a text identification result is sent by the text identification module 6 to the smart wearable device or the smart mobile device. Image information can be conveniently and quickly collected by a smart wearable device or a smart mobile device, a text identification result can be received, meter display identification efficiency and a level of smartness in a meter reading number are increased, degree of human involvement is reduced, and an error rate, data loss, or a risk of falsification is reduced. Furthermore, the text identification module 6 finds a character portion position in the display area 22 of target data, marks a coordinate point, performs collation and identification, and converts identified character content into text. An identification result of the text identification module 6 includes a text identification result and reliability corresponding to the text identification result. Accuracy of a text identification result can be determined on the basis of a numerical value of reliability that is an evaluation numerical value by identification state determination of each part in an identification process. Specifically, the text identification module 6 is an OCR identification module, an OCR identification technique is matured, cost is also low, and efficiency of text identification can be improved.

In a preferred embodiment of the present invention, the text detection module 5 identifies size data of the display area 22 of target data based on size data of a QR code in image information. Identifying size data of a display area of target data based on size data of a QR code is advantageous for improving accuracy of identification of target data display area, and improves accuracy of text identification.

Specifically, the size data includes numerical values such as the number of pixels, a length, and a width, and the size data of a QR code may be different from the size data corresponding to the display area 22 of target data depending on a meter type. The size data of the display area 22 of target data in the meter type is identified by a one-to-one correspondence between the QR code and the size data of the display area 22 of the target data, and the display area 22 of the target data is identified on a plurality of surfaces, which is advantageous for improving efficiency of identification of the display area 22 of the target data.

Further, there is a predetermined positional relationship between the display area 22 of target data and a display area of a figure identification code, and, by associating this positional relationship with the display area 22 of the figure identification code, the display area 21 of target data can be identified. For example, a shifted area having a predetermined length at different positions (upper left, lower left, upper right, and lower right) of the display area 21 shifted from a figure identification code is identified. Furthermore, when a shifted area is identified, whether or not the shifted area is the display area 22 of target data may be tested by an identification test. Specifically, the identification test is performed in an area shifted by 5 cm from a lower right position of the display area 21 of a figure identification code. In the identification test, for example, a length of a character in the area (for example, the length is six), a type of a character (type of a character is a number, an alphabet, or the like), or whether or not specific text is included is tested. According to an identification result, in a case of a number or an alphabet having a character length of six, the area belongs to the display area 22 of target data. In some embodiments, since the display area 22 of target data is usually provided at the position of a power button (POWER/on) or another button of a meter, when the identification test is performed, the display area 22 of target data may be identified by testing an area shifted by a predetermined length from the power button. Different identification methods may be employed for different meter types, and are not limited to examples described in the present invention.

In a preferred embodiment of the present invention, one or a plurality of the text identification module 6, the text detection module 5, and the meter type identification module 4 are provided in a smart wearable device or a smart mobile device.

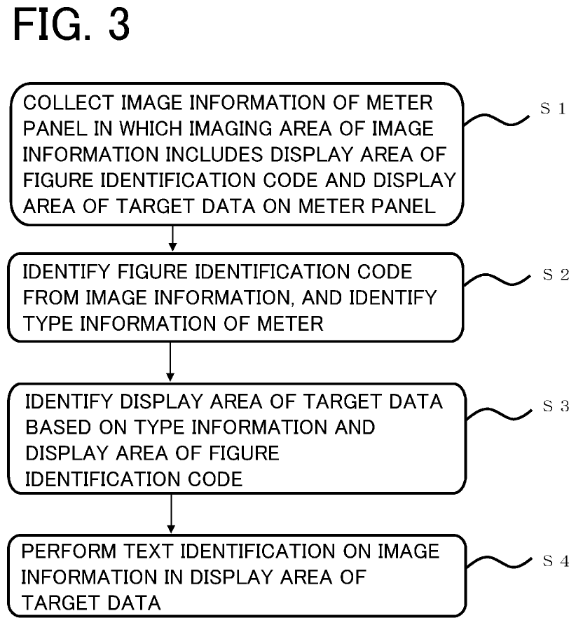

As illustrated in FIG. 3, in a manner corresponding to the first embodiment of the present invention, there is provided a meter display identification method in which a step below is further included, and the figure identification code 1 having type information of a meter is displayed on the meter panel 2 of the meter.

S1: Image information of the meter panel 2 in which an imaging area of image information includes the display area 21 of a figure identification code and the display area 22 of target data on the meter panel.

S2: The figure identification code 1 is identified from the image information, and type information of a meter is identified.

S3: The display area 22 of target data is identified based on the type information and the display area 21 of the figure identification code.

S4: Text identification is performed on image information in the display area 22 of the target data.

The present invention employs a means for individually identifying the figure identification code 1 and the display area 22 of target data, and identifies the display area 22 of target data based on type information of a meter and the display area 21 of a figure identification code. In this manner, complexity of identification of the display area 22 of target data is simplified, efficiency of identification of target data and accuracy of identification of target data are improved, and efficiency and accuracy of meter display are improved by intelligent reading of target data as compared with artificial reading and recording of meter display.

### Second Embodiment

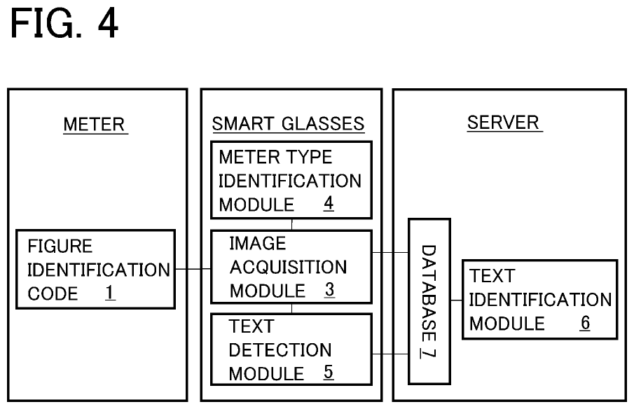

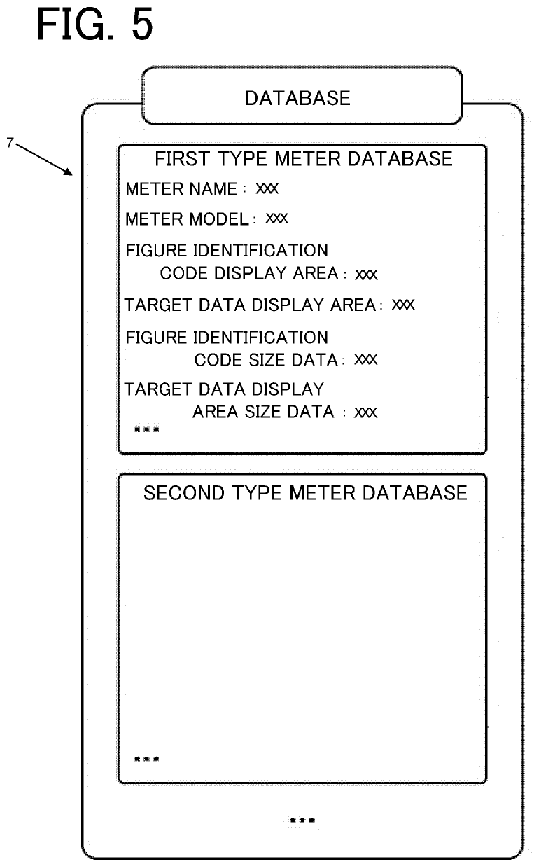

As illustrated in FIGS. 4 and 5, a second embodiment of the present invention provides a meter display identification system basically having the same configuration as that of the first embodiment, and a difference of these is that the meter display identification system provided by the second embodiment of the present invention further includes a database 7. In the database 7, type information of a meter, the display area 21 of a figure identification code, and the display area 22 of target data are stored in association with each other, and the database 7 is obtained by learning using image information of meters of a plurality of specific types as a reference data set. Note that the display area 21 of a figure identification code and the display area 22 of target data may be images stored in an image format such as jpg, JPEG, or png, or may be size data of a display area defined by a data format.

According to the above embodiment, meter type information in the database 7 is compared with meter type information of the figure identification code 1, so that type information of a meter is acquired, and the display area 21 of a figure identification code in the database 7 is compared with image information acquired by the image acquisition module 3, so that the display area 21 of the figure identification code can be acquired, and the display area 22 of target data can be identified based on the display area 21 of a figure identification code and the type information, or the display area 22 of target data in the database 7 is collated with the image information acquired by the image acquisition module 3, so that the display area 22 of target data can be acquired, and accuracy of identification of the display area 22 of target data can be improved. Further, since expanding information such as type information of a meter, the display area 21 of a figure identification code, and the display area 22 of target data in the database 7 is advantageous to increase a sample amount in the database 7 and improve collation efficiency, the display area 22 of target data is acquired more quickly and identification efficiency of the identification system is improved.

In a specific example of the present invention, the database 7 performs identification learning by using an OCR deep learning engine of PaddlePaddle.

In a preferred embodiment of the present invention, information stored in the database 7 is not limited to information such as type information of a meter, the display area 21 of a figure identification code, and the display area 22 of target data, but also includes a text data set including a character, an alphabet, a number, and the like corresponding to text identification.

### Third Embodiment

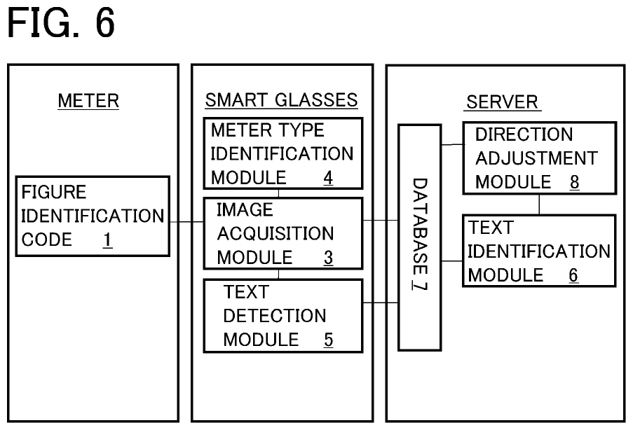

As illustrated in FIG. 6, a third embodiment of the present invention provides the meter display identification system that is basically the same as the configurations of the first and second embodiments, and a difference between these lies in that the meter display identification system provided by the third embodiment of the present invention further includes a direction adjustment module 8 for adjusting an angle of inclination or rotation of image information in the display area 22 of target data.

By adjusting an angle of inclination or rotation of image information by the direction adjustment module 8, it is possible to reduce interference with identification of a display area of target data by other pieces of data in a meter, to perform identification to the display area 22 of target data more accurately, and to improve accuracy of text identification.

In a preferred embodiment of the present invention, the direction adjustment module 8 adjusts an angle of inclination or rotation of image information in the display area 22 of target data based on an angle of inclination or rotation of a figure identification code. According to the above mode, accuracy of an angle of inclination or rotation identified by the direction adjustment module 8 can be further improved, which in turn improves text identification efficiency.

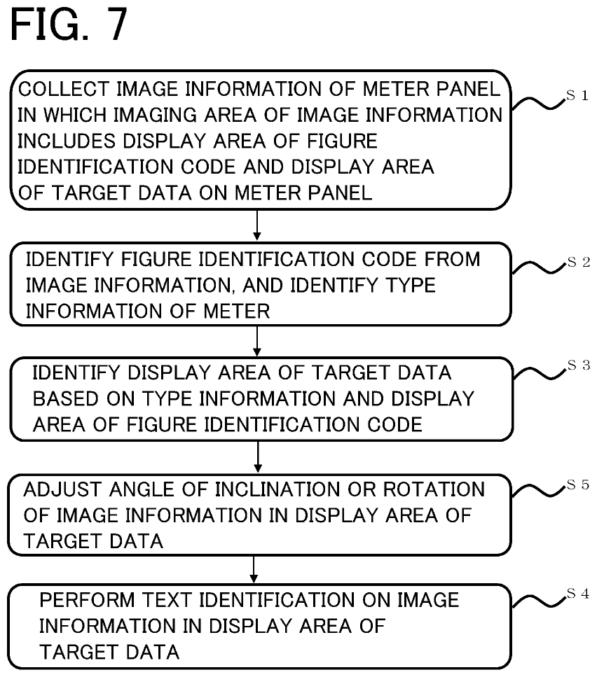

As illustrated in FIG. 7, in a manner corresponding to the third embodiment of the present invention, the meter display identification method is provided, and a difference from the identification method of the first embodiment lies in further including S5 of adjusting an angle of inclination or rotation of image information in the display area 22 of target data. According to the above method, it is advantageous to improve efficiency of identification of the display area 22 of target data and further improve text identification efficiency.

### Fourth Embodiment

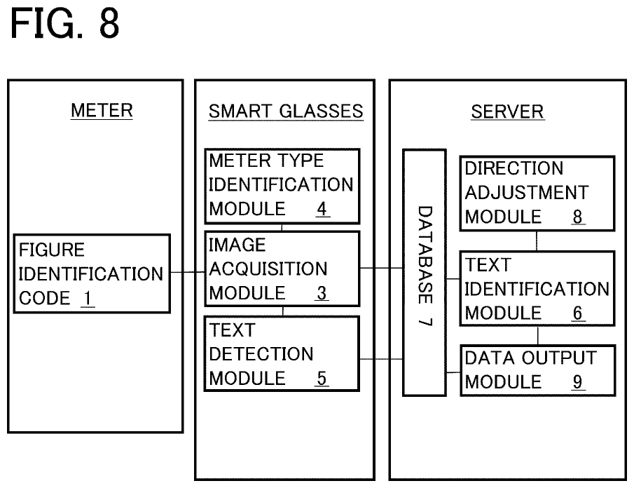

As illustrated in FIG. 8, a fourth embodiment of the present invention provides the meter display identification system similar to the configurations of the first, second, and third embodiments, and a difference of these lies in that the meter display identification system provided by the fourth embodiment of the present invention further includes a data output module 9 that outputs identified text. By directly outputting data as compared with artificial recording and data transfer, convenience and efficiency of data use are enhanced, and a risk of data loss and falsification is reduced. Specifically, by storing identified text in a predetermined format such as a CSV file and uploading or introducing the text directly into a laboratory information management system communicatively connected to a meter, a text identification result can be directly downloaded from the laboratory information management system, safety of data transfer is guaranteed, and a risk of falsification or loss of target data is reduced.

Further, the meter display identification system provided by the present invention may be a function module of a laboratory information management system that can be directly used by a smart wearable device or a smart mobile device. A text identification result that is identified and checked is directly mapped to a test result so that a human error during this process is reduced.

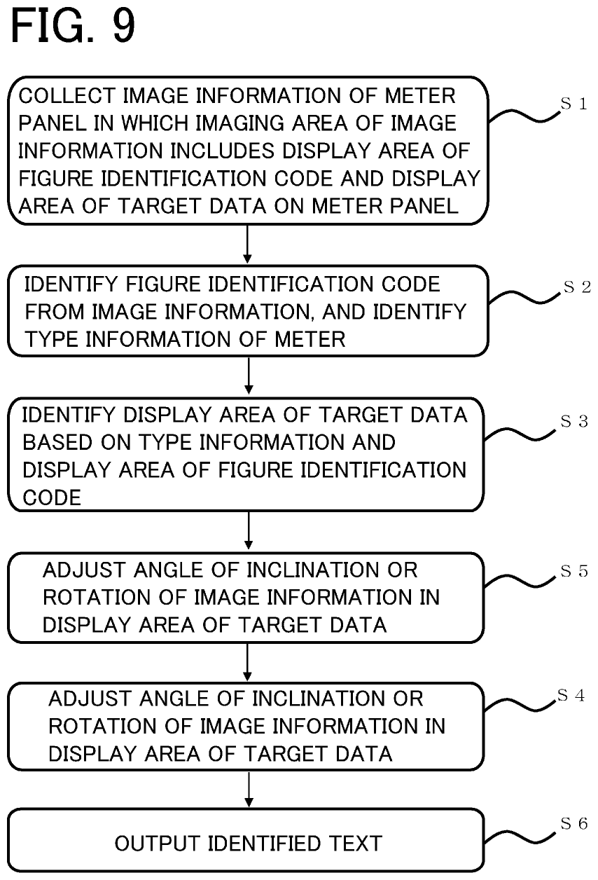

As illustrated in FIG. 9, in a manner corresponding to the fourth embodiment of the present invention, the present invention provides the meter display identification method, and a difference from the third embodiment lies in further including S6 of outputting identified text.

By directly outputting data as compared with artificial recording and data transfer, convenience and efficiency of data use are enhanced, and a risk of data loss and falsification is reduced.

The above describes only preferred examples of the present invention, and does not limit the present invention, and any revision, equivalent replacement, improvement, and the like within the spirit and principle of the present invention should fall within the protection scope of the present invention.

### DESCRIPTION OF REFERENCE SIGNS

1 figure identification code
2 meter panel
21 display area of figure identification code
22 display area of target data
3 image acquisition module
4 meter type identification module
5 text detection module
6 text identification module
7 database
8 direction adjustment module
9 data output module

1. A meter display identification system for identifying type information of a meter included in a figure identification code displayed on a meter panel side of the meter, the meter display identification system comprising:
an image acquisition module configured to collect image information of the meter panel, wherein an imaging area of the image information includes a display area of the figure identification code and a display area of target data on the meter panel;
a meter type identification module configured to identify the figure identification code from image information collected by the image acquisition module;
a text detection module configured to identify a display area of the target data based on a display area of the figure identification code; and
a text identification module configured to perform text identification on image information in a display area of the target data.

2. The meter display identification system according to claim 1, wherein
the meter type identification module is configured to identify type information of the meter, and
the text detection module is configured to identify a display area of the target data based on the type information.

3. A meter display identification system for identifying type information of a meter included in a figure identification code displayed on a meter panel side of the meter, the meter display identification system comprising:
an image acquisition module configured to collect image information of the meter panel, wherein an imaging area of the image information includes a display area of the figure identification code and a display area of target data on the meter panel;
a meter type identification module configured to identify type information of the meter by identifying the figure identification code from image information collected by the image acquisition module;
a text detection module configured to identify a display area of the target data based on the type information; and
a text identification module configured to perform text identification on image information in a display area of the target data.

4. The meter display identification system according to claim 3, wherein
the image acquisition module is installed in a smart wearable device or a smart mobile device, and
the text identification module is configured to send a text identification result to the smart wearable device or the smart mobile device.

5. The meter display identification system according to claim 3, further comprising a database, wherein
the database stores type information of the meter, a display area of the figure identification code, and a display area of the target data in association with each other, and the database is obtained by learning of image information of meters of a plurality of specific types as a reference data set.

6. The meter display identification system according to claim 3, further comprising a direction adjustment module for adjusting an angle of inclination or rotation of image information in a display area of the target data.

7. The meter display identification system according to claim 6, wherein
the direction adjustment module is configured to adjust an angle of inclination or rotation of image information in a display area of the target data based on an angle of inclination or rotation of the figure identification code.

8. The meter display identification system of claim 3, further comprising a data output module that outputs text identified by the text identification module.

9. The meter display identification system according to claim 3, wherein
an identification result of the text identification module includes a text identification result and reliability corresponding to the text identification result.

10. The meter display identification system according to claim 3, wherein
the figure identification code is a QR code provided in a display area of target data adjacent to a meter panel.

11. The meter display identification system according to claim 10, wherein
the text detection module is configured to identify size data of a display area of the target data based on size data of a QR code in the image information acquired by the image acquisition module.

12. A meter display identification method used in a meter display identification system for identifying type information of a meter included in a figure identification code displayed on a meter panel side of the meter, the meter display identification method comprising the steps of:
collecting image information of the meter panel, wherein an imaging area of the image information includes a display area of the figure identification code and a display area of target data on the meter panel;
identifying the figure identification code from the image information and identifying type information of the meter;
identifying a display area of the target data based on the type information and a display area of the figure identification code; and
performing text identification on image information in a display area of the target data.
